(19) United States
(12) Patent Application Publication
(10) Pub. No.: US 2026/0159991 A1
(43) Pub. Date: Jun. 11, 2026

(54) THERMAL RADIATION PROFILE CONTROL

(71) Applicant: Applied Materials, Inc., Santa Clara, CA (US)

(72) Inventors: Erica de Leon Sanchez, San Francisco, CA (US); Flora Fong-Song Chang, Saratoga, CA (US); Thomas Kirschenheiter, Tempe, AZ (US); Maribel Maldonado-Garcia, Valle de Santiago (MX); Zuoming Zhu, Sunnyvale, CA (US); Abhishek Dube, Fremont, CA (US); Errol Antonio C. Sanchez, Tracy, CA (US)

(21) Appl. No.: 18/969,493

(22) Filed: Dec. 5, 2024

(51) Int. Cl. C30B 25/16; C30B 29/68

(52) U.S. Cl. CPC C30B 25/16; C30B 29/68

(57) ABSTRACT

A method includes initiating a process with respect to a substrate located on a substrate support apparatus, obtaining, from a set of thermal radiation detectors located underneath the substrate support apparatus, thermal radiation measurements each corresponding to a respective location of the substrate support apparatus, determining a thermal radiation profile of the substrate support apparatus based on the thermal radiation measurements, determining whether the thermal radiation profile of the substrate support apparatus satisfies a threshold condition, in response to determining that the thermal radiation profile of the substrate support apparatus does not satisfy the threshold condition, modifying operation of a first set of heat sources to adjust the thermal radiation profile of the substrate support apparatus, and modifying, based at least in part on the operation of the first set of heat sources, operation of a second set of heat sources to adjust a thermal radiation profile of the substrate.

### TECHNICAL FIELD

Embodiments of the present disclosure generally relate to metrology, and more specifically relate to thermal radiation profile control for layer-to-layer uniformity during deposition processes.

### BACKGROUND

Substrates such as wafers can be processed for a wide variety of applications, including the fabrication of integrated devices and microdevices. One method of processing substrates includes depositing a material, such as a semiconductor material or a conductive material, on an upper surface of the substrate.

Some deposition processes are epitaxial deposition processes. Epitaxial deposition processes can be used to deposit epitaxial layers, or epitaxial films, of various materials on a surface of a substrate in a processing chamber. More specifically, an epitaxial layer can be a crystalline layer of material grown on a substrate, where the crystalline material mimics or aligns with the crystal structure of the underlying substrate. Superlattice epitaxy is one type of epitaxial deposition process in which a superlattice is formed on a substrate. Superlattice epitaxy refers to a specialized form of epitaxial growth in which alternating, ultra-thin layers of different materials are deposited to create a periodic structure, known as a superlattice. A goal of superlattice epitaxy is to form a layered material where the individual layers are only a few atoms or molecules thick. The thickness of the individual layers can range from a few atomic monolayers to tens of nanometers.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some embodiments, a system includes a memory, and at least one processing device, operatively coupled with the memory, to initiate a process with respect to a substrate located on a substrate support apparatus, obtain, from a set of thermal radiation detectors located underneath the substrate support apparatus, a plurality of thermal radiation measurements, each thermal radiation measurement of the plurality of thermal radiation measurements corresponding to a respective location of the substrate support apparatus, determine a thermal radiation profile of the substrate support apparatus based on the plurality of thermal radiation measurements, determine whether the thermal radiation profile of the substrate support apparatus satisfies a threshold condition, in response to determining that the thermal radiation profile of the substrate support apparatus does not satisfy the threshold condition, modify operation of a first set of heat sources to adjust the thermal radiation profile of the substrate support apparatus, and modify, based at least in part on the operation of the first set of heat sources, operation of a second set of heat sources to adjust a thermal radiation profile of the substrate.

In some embodiments, a method includes initiating, by at least one processing device, a process with respect to a substrate located on a substrate support apparatus, obtaining, by the at least one processing device from a set of thermal radiation detectors located underneath the substrate support apparatus, a plurality of thermal radiation measurements, each thermal radiation measurement of the plurality of thermal radiation measurements corresponding to a respective location of the substrate support apparatus, determining, by the at least one processing device, a thermal radiation profile of the substrate support apparatus based on the plurality of thermal radiation measurements, determining, by the at least one processing device whether the thermal radiation profile of the substrate support apparatus satisfies a threshold condition, in response to determining that the thermal radiation profile of the substrate support apparatus does not satisfy the threshold condition, modifying, by the at least one processing device, operation of a first set of heat sources to adjust the thermal radiation profile of the substrate support apparatus, and modifying, by the at least one processing device based at least in part on the operation of the first set of heat sources, operation of a second set of heat sources to adjust a thermal radiation profile of the substrate.

In some embodiments, a system includes a processing chamber including a substrate support apparatus, a first set of thermal radiation detectors located below the substrate support apparatus, a second set of thermal radiation detectors located above the substrate support apparatus, a first set of heat sources configured to heat the substrate support apparatus, a second set of heat sources configured to heat a substrate located on the substrate support apparatus, and at least one system controller. The at least one system controller is to initiate a process with respect to the substrate, obtain, from the first set of thermal radiation detectors, a plurality of thermal radiation measurements, each thermal radiation measurement of the plurality of thermal radiation measurements corresponding to a respective location of the substrate support apparatus, determine a thermal radiation profile of the substrate support apparatus based on the plurality of thermal radiation measurements, determine whether the thermal radiation profile of the substrate support apparatus satisfies a threshold condition, in response to determining that the thermal radiation profile of the substrate support apparatus does not satisfy the threshold condition, modify operation of the first set of heat sources to adjust the thermal radiation profile of the substrate support apparatus, and modify, based on the operation of the first set of heat sources, operation of the second set of heat sources to adjust a thermal radiation profile of the substrate.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a schematic cross-sectional view of a system for substrate processing, according to some embodiments.

FIGS. 2A-2B are schematic cross-sectional views of a system that can implement thermal radiation profile control for epitaxial layer-to-layer uniformity, according to some embodiments.

FIGS. 3A-3B are diagrams of an example substrate support apparatus and set of bottom thermal radiation detectors, according to some embodiments.

FIG. 4 is a diagram illustrating a method of implementing a variable threshold condition for thermal radiation profile control during an epitaxial deposition process, according to some embodiments.

FIG. 5 is a flowchart of a method for implementing thermal radiation profile control for epitaxial layer-to-layer uniformity, according to some embodiments.

FIG. 6 depicts a diagrammatic representation of a machine in the example form of a computing device within which a set of instructions, for causing the machine to perform any one or more of the methodologies discussed herein, can be executed.

### DETAILED DESCRIPTION OF EMBODIMENTS

Embodiments of the present disclosure are directed to thermal radiation profile control for layer-to-layer uniformity for deposition processes. In some processing chambers, a substrate support assembly can include a substrate support apparatus used to support the substrate as well as transfer heat to the substrate during processing. For example, a substrate support apparatus can include a susceptor. The temperature of the substrate support apparatus and substrate can be controlled through heat sources. Examples of heat sources include heating lamps, resistive heaters, light emitting diodes (LEDs), lasers, etc.

For some deposition processes, such as epitaxial deposition processes (e.g., superlattice epitaxy), thermal radiation profiles of the substrate support apparatus (e.g., the susceptor) and/or a substrate located on the substrate support assembly may not be monitored or controlled. For example, a thermal radiation profile of a substrate support apparatus can be defined as the difference between thermal radiation measured with respect to a center location of the substrate support apparatus and thermal radiation measured with respect to at least one outer location of the substrate support apparatus. An outer location refers to a location at some distance away from the center location, such as within an edge region. In some embodiments, the thermal radiation profile of the substrate support apparatus is a temperature profile defined as a difference between a temperature at the center location and a temperature at least one outer location (e.g., at least one location having a distance away from the center location).

Due to heat transfer between the substrate support apparatus and the substrate, temperature distribution of the substrate support apparatus can affect temperature distribution of the substrate. The lack of monitoring and/or control of the thermal radiation profile of the substrate support apparatus can result in thermal radiation profile drift with respect to a reference temperature difference over time during a deposition process such as an epitaxial deposition process (e.g., superlattice epitaxy). The thermal radiation profile drift can lead to non-uniformity of deposition or growth of material across the substrate during the deposition process (e.g., layers of a superlattice film), as well as a lack of process-to-process, or run-to-run, repeatability.

Embodiments described herein address at least the above-noted drawbacks by providing for thermal radiation profile control for coating or layer uniformity (e.g., epitaxial layer-to-layer uniformity) during a process performed on a substrate. In some embodiments, the deposition process is an epitaxial deposition process. For example, an epitaxial deposition process can be superlattice epitaxy. Other examples of deposition processes include chemical vapor deposition (CVD), atomic layer deposition (ALD), physical vapor deposition (PVD), etc. Embodiments described herein can be applied during a deposition process to reduce thermal radiation profile drift (e.g., temperature profile drift) during the deposition process, and thus improve uniformity of material deposition or growth.

For example, a system described herein can include a processing chamber configured to perform a deposition process (e.g., superlattice epitaxy). In some embodiments, the deposition chamber includes an epitaxial deposition reactor (“epi reactor”). Alternatively, other types of deposition chambers may be used. The processing chamber can include a substrate support assembly including a substrate support apparatus configured to receive a substrate to be processed within the processing chamber. In some embodiments, the substrate support apparatus includes a susceptor.

A system described herein can include heat sources use to control the temperature of the substrate support apparatus and the substrate. Examples of heat sources include as heating lamps, resistive heaters, LEDs, lasers, etc. For example, the heat sources can include a set of bottom heat sources located below the substrate support apparatus and configured to heat the substrate support apparatus. As another example, the heat sources can include a set of top heat sources located above the substrate and configured to heat the substrate.

A system described herein can further include a thermal profile measurement and control subsystem (“subsystem”) to implement thermal profile measurement and control for layer-to-layer uniformity (e.g., epitaxial layer-to-layer uniformity) during a deposition process performed on the substrate. In some embodiments, the subsystem is an in-situ subsystem. As will be described in further detail, the subsystem is used to control operation of the heat sources in real-time or near real-time during a deposition process to reduce temperature drift and thus improve uniformity.

To implement thermal profile measurement, the subsystem can include multiple thermal radiation detectors (“detectors”) configured to measure thermal radiation (e.g., temperature) at various locations with respect to the substrate support apparatus and/or substrate during a deposition process. In some embodiments, a detector is a pyrometer. In some embodiments, a detector includes a thermometer.

More specifically, the detectors can include a set of bottom detectors located below the substrate support apparatus. In some embodiments, the set of bottom detectors includes a bottom center detector and at least one bottom outer detector. The bottom center detector can measure thermal radiation emitted by a center location of the substrate support apparatus, and each bottom outer detector can measure thermal radiation emitted by a respective outer location of the substrate support apparatus. For example, an outer location of the substrate support apparatus can be a location within an edge region of the substrate support apparatus. In some embodiments, different bottom outer detectors are configured to detect a temperature at different distances or radii (e.g., from the center location of the substrate support apparatus). In some embodiments, the detectors further include a set of top detectors located above the substrate. In some embodiments, the set of top detectors includes a top center detector and at least one top outer detector. The top center detector can measure thermal radiation emitted by a center location of the substrate, and each top outer detector can measure thermal radiation emitted by a respective outer location of the substrate. For example, an outer region of the substrate can be a location within an edge region of the substrate. In some embodiments, different top outer detectors are configured to detect a temperature at different distances or radii (e.g., from the center location of a substrate).

The subsystem can include at least one system controller to implement thermal radiation profile control. For example, thermal radiation profile control can include temperature profile control.

Implementing thermal radiation profile control can include controlling a bottom thermal radiation profile of the substrate support apparatus based on a set of inputs. The set of inputs can include bottom thermal radiation measurements (e.g., temperature measurements) made by, and received from, the set of bottom detectors. For example, to control the bottom thermal radiation profile, the at least one system controller can receive a bottom center thermal radiation measurement made by the bottom center detector (T_{BC}), and at least one bottom outer thermal radiation measurement made by the at least one bottom outer detector (T_{BS}). The at least one system controller can determine whether the bottom thermal radiation measurements satisfy a criterion such as a threshold condition. For example, the set of inputs can further include a predefined thermal radiation condition (e.g., a thermal radiation difference threshold). In some embodiments, the predefined thermal radiation condition is user-defined. For example, the predefined thermal radiation condition can be experimentally determined by a user. The at least one system controller can determine whether the bottom thermal radiation measurements satisfy the threshold condition by analyzing the thermal radiation measurements and comparing to the predefined thermal radiation condition. In some embodiments, the predefined thermal radiation condition is based on a predefined thermal radiation (e.g., temperature) difference between the bottom center thermal radiation measurement and the at least one bottom outer thermal radiation measurement. For example, the predefined thermal radiation condition can be a single difference value or a range of difference values that correspond to a satisfactory thermal radiation profile across the substrate support apparatus. In these embodiments, the at least one system controller can determine a measured thermal radiation difference (e.g., temperature difference) between T_{BC} and T_{BS} (T_{BC}−T_{BS}), and then compare the measured thermal radiation difference to the predefined thermal radiation difference to determine whether the measured thermal radiation difference satisfies the predefined thermal radiation difference (e.g., is approximately equal to a predefined thermal radiation difference value or is within a predefined range of thermal radiation difference values).

In some embodiments, the threshold condition (e.g., the predefined thermal radiation condition) is a static threshold condition. More specifically, the threshold condition can remain the same throughout all steps of the epitaxial deposition process. The static threshold condition can be user-defined.

In some embodiments, the threshold condition is a variable threshold condition that varies throughout the epitaxial deposition process. Illustratively, if the threshold condition is a predefined thermal radiation (e.g., temperature) difference, then the predefined thermal radiation difference can be increased (e.g., by a fixed rate) throughout the epitaxial deposition process. In some embodiments, the threshold condition varies based on a block of steps (“block”) of the epitaxial deposition process. A block of an epitaxial deposition process includes multiple steps that form a repeatable loop. Illustratively, if the threshold condition is a predefined thermal radiation difference, then the predefined thermal radiation difference can be increased for a current block after the completion of a previous block. For example, the predefined thermal radiation difference can be increased by a fixed amount. In some embodiments, each block is assigned a respective predefined thermal radiation difference as a threshold condition. Each predefined thermal radiation difference can be user-defined. For example, at least one offset data structure (e.g., table) that defines the respective predefined thermal radiation difference for each block can be stored, and the at least one system controller can use the at least one offset data structure to determine the predefined thermal radiation difference for each block throughout the epitaxial deposition process.

If the at least one system controller determines that the bottom thermal radiation measurements do not satisfy the threshold condition (e.g., the measured thermal radiation difference does not satisfy the predefined thermal radiation difference), then the at least one system controller can take corrective action by modifying operation of the set of bottom heat sources. More specifically, the at least one system controller can cause a modification of the power generated, or output, by the set of bottom heat sources in order for the bottom thermal radiation measurements to satisfy the threshold condition (e.g., the measured thermal radiation difference satisfies the predefined thermal radiation difference). This may include changing a ratio between a power delivered to a bottom inner zone heat source and an bottom outer zone heat source, for example.

In some embodiments, the set of bottom heat sources includes a bottom inner zone of heat sources used to heat the bottom center region of the substrate support apparatus, and a bottom outer zone of heat sources used to heat a bottom outer region of the substrate support apparatus.

In some embodiments, the power generated by the bottom inner zone and the power generated by the bottom outer zone are dependently controlled (e.g., dependently controlled zones). For example, the set of bottom heat sources can be allocated a power budget, and the bottom inner zone and the bottom outer zone can be allocated respective amounts of power from the power budget. More specifically, the bottom inner zone can be allocated a first amount of power (e.g., percentage) of the power budget and the bottom outer zone can be allocated a second amount of power (e.g., percentage) of the power budget, where the sum of the first amount of power and the second amount of power is approximately equal to the power budget (e.g., the percentages of the power budget add up to 100%). Thus, any increase or decrease to the first amount of power can result in a corresponding decrease or increase, respectively, to the second amount of power in accordance with the power budget (and vice versa). Accordingly, in these embodiments, the at least one system controller can take corrective action by adjusting (e.g., increasing or decreasing) the first amount of power allocated to the bottom inner zone by a given magnitude and adjusting (e.g., decreasing or increasing) the second amount of power allocated to the bottom outer zone by the given magnitude in a manner determined to cause the bottom thermal radiation measurements to satisfy the threshold condition while maintaining the power budget.

In some embodiments, the power generated by the bottom inner zone and the power generated by the at least one bottom outer zone are independently controlled (e.g., independently controlled zones). For example, the power generated by the bottom inner zone can be adjusted by any amount without regard to the amount of power generated by the at least one bottom outer zone, and vice versa.

Implementing thermal radiation profile control can further include controlling a top thermal radiation profile (e.g., temperature profile) of the substrate based at least in part on the bottom thermal radiation profile control. More specifically, the at least one system controller can control operation of a set of top heat sources used to heat the substrate (e.g., power generated by the set of top heat sources). In some embodiments, the at least one system controller controls operation of the set of top heat sources by adjusting the power generated by the set of top heat sources by an amount proportional to the power generated by the set of bottom heat sources. More specifically, the power generated by the set of top heat sources can be equal to the power generated by the set of bottom heater sources multiplied by an adjustment factor.

In some embodiments, and similar to the set of bottom heat sources, the set of top heat sources includes top inner zone of heat sources used to heat the top center region of the substrate, and a top outer zone of heat sources used to heat at least the top outer region of the substrate. In these embodiments, the at least one system controller can proportionally adjust the power generated by the top inner zone and/or the power generated by the top outer zone. For example,

In some embodiments, the power generated by the top inner zone and the power generated by the top outer zone are dependently controlled (e.g., similar to the set of bottom heat sources). In some embodiments, the power generated by the top inner zone and the power generated by the top outer zone are independently controlled.

In some embodiments, the adjustment factor is determined based on a ratio between a top heat source metric associated with the set of top heat sources, and a bottom heat source metric associated with the set of bottom heat sources. For example, a top heat source metric can be a number of top heat sources (e.g., of the top inner zone and/or the top outer zone), and a bottom heat source metric can be a number of bottom heat sources (e.g., of the bottom inner zone and/or the bottom outer zone). As another example, a top heat source metric can be a density of top heat sources (e.g., of the top inner zone and/or the top outer zone), and a bottom heat source metric can be a density of bottom heat sources (e.g., of the bottom inner zone and/or the bottom outer zone). As yet another example, a top heat source metric can be an amount of power generated by the set of top heat sources (e.g., by the top inner zone and/or the top outer zone), and a bottom heat source metric can be an amount of power generated by the set of bottom heat sources (e.g., by the bottom inner zone and/or the bottom outer zone). However, any suitable heat source metric can be used to determine the adjustment factor in accordance with embodiments described here. In some embodiments, the adjustment factor is determined based on an analysis of a relationship or correlation between thermal radiation measurements made by the set of bottom detectors and thermal radiation measurements made by the set of top detectors.

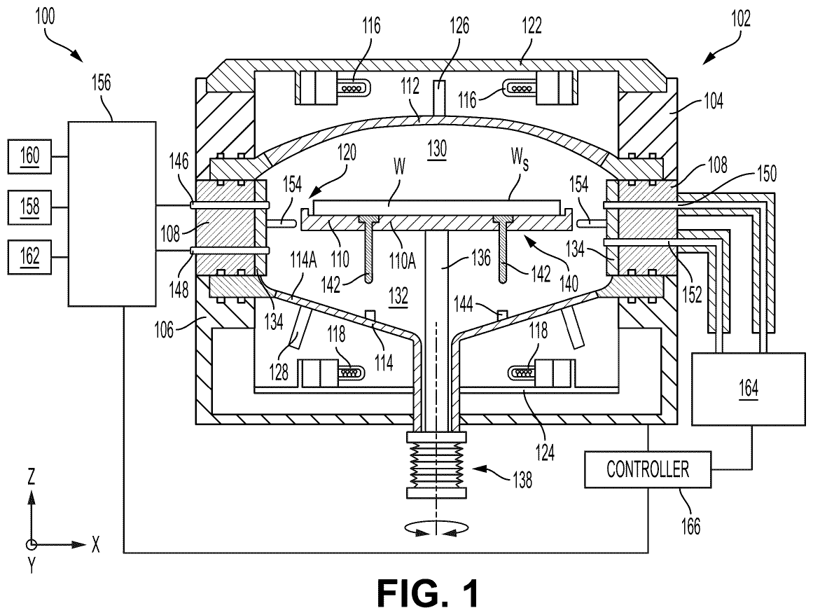

Accordingly, the at least one system controller can use a closed-loop control scheme to automatically control operation of the set of bottom heat sources (e.g., power generated by the set of bottom heat sources) based on a set of inputs, and use a dependent control scheme to automatically control operation of the set of top heat sources (e.g., power generated by the set of top heat sources) based on the operation of the set of bottom heat sources. Further details regarding implementing thermal radiation profile control for epitaxial layer-layer uniformity will be described below with reference to FIGS. 1-6.

Embodiments of the present disclosure provide various technical advantages. For example, embodiments described herein can enable real-time or near real-time control of heat sources used to form layers of material during an epitaxial deposition process to improve electronic device quality and yield. As another example, embodiments described herein can be used to analyze substrate-to-substrate operation during production in order to achieve a target substrate run, such as a reference baseline substrate run, an average run of multiple substrate runs, etc.

FIG. 1 is a schematic cross-sectional view of a system 100 for substrate processing, according to some embodiments. The system 100 includes a processing chamber 102. In one or more embodiments, the processing chamber 102 is a deposition chamber. In one embodiment, which can be combined with other embodiments, the processing chamber 102 is an epitaxial deposition chamber. The processing chamber 102 is utilized to grow an epitaxial film on a substrate W. The processing chamber 102 creates a cross-flow of precursors across a surface Wₛ of the substrate W to deposit a film

The processing chamber 102 includes an upper body 104, a lower body 106 disposed below the upper body 104, and a flow module 108 disposed between the upper body 104 and the lower body 106. The upper body 104, the flow module 108, and the lower body 106 form a chamber body. Disposed within the chamber body is a substrate support 110, an upper window 112 (such as an upper dome), a lower window 114 (such as a lower dome), upper heat sources 116, and lower heat sources 118.

The substrate support 110 is disposed between the upper window 112 and the lower window 114. The substrate support 110 includes a front surface 120 that faces the upper window 112 and supports the substrate W. The upper heat sources 116 are disposed between the upper window 112 and a lid 122. The lower heat sources 118 are disposed between the lower window 114 and a floor 124. The upper window 112 is an upper dome and is formed of an energy transmissive material, such as quartz. The lower window 114 is a lower dome and is formed of an energy transmissive material, such as quartz. In some embodiments, the heat sources 116, 118 include lamps. Other heat sources are contemplated, such as resistive heaters, light emitting diodes (LEDs), and/or lasers.

The processing chamber 102 may include one or more temperature sensors 126, 128, such as optical pyrometers, which measure temperatures within the processing chamber 102. The temperature sensor 126 (e.g., a top pyrometer) may be disposed on an upper side of the upper window 112. The temperature sensor 128 (e.g., a bottom pyrometer) may be disposed on a lower side of the lower window 114.

A process volume (also referred to as an “upper volume”) 130 and a purge volume (also referred to as a “lower volume”) 132 are formed between the upper window 112 and the lower window 114. The process volume 130 and the purge volume 132 are part of an internal volume defined at least partially by the upper window 112, the lower window 114, and one or more liners 134.

The internal volume has the substrate support 110 disposed therein. The purge volume 132 is on the opposite of the substrate support 110 from the front surface 120 and a substrate W disposed thereon. The substrate support 110 is attached to a shaft 136. The shaft 136 is connected to a motion assembly 138. The motion assembly 138 includes one or more actuators and/or adjustment devices that provide movement and/or adjustment for the shaft 136 and/or the substrate support 110 within the processing volume 130.

The substrate support 110 may include lift pin holes 140 disposed therein. The lift pin holes 140 are sized to accommodate a lift pin 142 for lowering and/or lifting of the substrate W from the substrate support 110 before and/or after a deposition process is performed. The lift pins 142 may rest on lift pin stops 144 when the substrate support 110 is lowered from a process position to a transfer position.

The flow module 108 includes a process inlet passage 146 in fluid communication with the process volume 130, and a purge inlet passage 148 in fluid communication with the purge volume 132. The flow module 108 further includes a process outlet passage 150 in fluid communication with the process volume 130, and a purge outlet passage 152 in fluid communication with the purge volume 132. The process inlet passages 146 and the purge inlet passage 148 are disposed on the opposite side of the flow module 108 from the process outlet passage 150 and the purge outlet passage 152. One or more flow guides 154 are disposed below the process inlet passage 146 and the process outlet passage 150. The one or more flow guides 154 are disposed above the purge inlet passage 148. In one or more embodiments, the one or more flow guides 154 include a pre-heat ring. One or more liners 134 are disposed on an inner surface of the flow module 108 and protect the flow module 108 from reactive gases used during deposition operations and/or cleaning operations. The process inlet passage 146 and the purge inlet passage 148 are each positioned to flow a gas parallel to the surface Wₛ of a substrate W disposed within the process volume 130. The process inlet passage 146 and the purge inlet passage 148 are fluidly connected to a gas supply system 156 which coordinates the gases to be delivered to the processing chamber 102. One or more process gas sources 158, one or more cleaning gas sources 160, and one or more purge gas sources 162 are fluidly connected to the gas supply system 156. In one or more embodiments, the one or more process gas sources 158 include one or more reactive gas sources and one or more carrier gas sources.

The process outlet passage 150 and the purge outlet passage 152 are fluidly connected to an exhaust pump 164 (e.g., a vacuum pump).

One or more process gases supplied to the gas supply system 156 using the one or more process gas sources 158 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of hydrogen (H₂), argon (Ar), helium (He), and/or nitrogen (N₂)). One or more cleaning gases supplied using the one or more cleaning gas sources 160 can include one or more of hydrogen (H₂) and/or chlorine (Cl). In one embodiment, which can be combined with other embodiments, the one or more process gases include silicon phosphide (SiP) and/or phosphine (PH₃), and the one or more cleaning gases include hydrochloric acid (HCl). The present disclosure contemplates that the carrier gas(es), purge gas(es), and/or cleaning gas(es) are all candidates for recycling described herein.

As shown, the system 100 includes a system controller (“controller”) 166 in communication with the processing chamber 102. The controller 166 is used to control processes and methods, such as the operations of the methods described herein. The controller 166 is in communication with the exhaust pump 164 and the gas supply system 156. The controller 166 controls the exhausted gas (exhausted from the processing chamber 102) using sensors disposed along the exhaust pump 164, and/or the gas supply system 156. By monitoring the purity content of the gas, the controller 166 can control the gas supply system 156 and determine (and control) where gas(es) flow in the system 100.

The controller 166 includes a central processing unit (CPU), a memory containing instructions, and support circuits for the CPU. The controller 166 controls various items directly, or via other computers and/or controllers. In one or more embodiments, the controller 166 is communicatively coupled to dedicated controllers, and the controller 166 functions as a central controller.

The controller 166 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 166 are coupled to the CPU for supporting the CPU (a processor). The support circuits include cache, power supplies, clock circuits, input/output circuitry and subsystems, and the like. Operational parameters (the pressure of a recycled gas, the purity of a recycled gas, the chemical makeup of a recycled gas) and operations are stored in the memory as a software routine that is executed or invoked to turn the controller 166 into a specific purpose controller to control the operations of the various systems/chambers/recycling systems/modules described herein. The controller 166 is configured to conduct any of the operations described herein. The instructions stored on the memory, when executed, cause one or more of operations of method 200 (described below) to be conducted.

The various operations described herein can be conducted automatically using the controller 166, or can be conducted automatically and/or manually with certain operations conducted by a user.

The controller 166 is configured to adjust output to controls of the system 100 based off of sensor readings, a system model, and stored readings and calculations. The controller 166 includes embedded software and a compensation algorithm to calibrate measurements. The controller 166 can include one or more machine learning algorithms and/or artificial intelligence algorithms that estimate optimized parameters for deposition operation(s), purge operation(s), and/or cleaning operation(s). The one or more machine learning algorithms and/or artificial intelligence algorithms can use, for example, a regression model (such as a linear regression model) or a clustering technique to estimate optimized parameters. The algorithm can be unsupervised or supervised.

In some embodiments, the gas supply system 156 is responsible for providing all gases to the processing chamber 102 regardless which gas source 158, 160, 162 supplies the gases. The gas supply system 156 is controlled by the controller 166.

An epitaxial deposition process can be performed to deposit layers on a surface Wₛ of a substrate W supported on the front surface 120 of the substrate support 110 disposed in the process volume 130 of the processing chamber 102. The epitaxial deposition process includes flowing one or more reactive gases from the one or more process gas sources 158 into the process volume 130 of the processing chamber 102. The one or more reactive gases enter the process volume 130 via the process inlet passage 146 above the one or more flow guides 145 and exit via the process outlet passage 150.

For example, the deposited layers may be alternating layers of first material (e.g., silicon (Si)) and second material (e.g., silicon germanium (SiGe)). Each layer can have a thickness of between about 50 Å and about 1000 Å. The number of pairs of layers of the first material and the second material is more than 2.

In some embodiments, the one or more reactive gases include a deposition gas and a carrier gas. The deposition gas includes a silicon or germanium-containing precursor and a dopant source. The dopant source may include a precursor phosphine (PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb). The dopant source may include a precursor diborane (B₂H₆), or trimethylgallium Ga(CH₃)₃, including p-type dopants such as boron (B) or gallium (Ga). The carrier gas may include nitrogen (N₂), argon (Ar), helium (He), or hydrogen (H₂).

During the epitaxial deposition process, a portion of the deposition gas may leak into the purge volume 132 between the flow guide 154 and the substrate support 110 and may form a coating on inner surfaces of the purge volume 132 (e.g., a back surface 110A of the substrate support 110 and an inner surface 114A of the lower window 114 as shown in FIG. 1). Since the epitaxial deposition process may be long (e.g., deposition of 100 pairs of silicon (Si) and silicon germanium (SiGe) layers), the coating may accumulate. This coating may cause inaccurate temperature measurement by the temperature sensor 128 (e.g., a bottom pyrometer) disposed on the lower window 114.

A coating removal process can be performed to reduce or eliminate the coating on the inner surfaces of the purge volume 132 (e.g., the back surface 110A of the substrate support 110 and the inner surface 114A of the lower window 114). The coating removal process includes flowing purge gas from the one or more purge gas sources 162 or cleaning gas from the one or more cleaning gas source 160 through the purge volume 132 of the processing chamber 102, via the purge inlet passage 148 and the purge outlet passage 152. The purge gas may include hydrogen (H₂) at a flow rate of more than 2 standard liters per minute (slm), and dilute the portion of the deposition gas flowed into the purge volume 132, preventing formation of a coating on the back surface 110A of the substrate support 110 and the inner surface 114A of the lower window 114. The cleaning gas may include chlorine containing etchant gas, removing the coating that is formed on the back surface 110A of the substrate support 110 and the inner surface 114A of the lower window 114. The purge gas or the cleaning gas may be prevented from leaking into the process volume 130, which may interfere with the epitaxial deposition process, since the purge gas or the cleaning gas flow through the purge volume 132 via the purge inlet passage 148 and the purge outlet passage 152 below the flow guides 154.

A temperature monitoring process can be performed to measure temperature of the inner surface of the purge volume 132 (e.g., the lower window 114) by the temperature sensor 128 (e.g., a bottom pyrometer) disposed on the lower window 114. The temperature measured with respect to the back surface 110A of the substrate support 110 on the opposite side of the substrate support 110 from a substrate W disposed thereon may not be affected by growth of a film on the substrate W. Further, the temperature measured with respect to the back surface 110A of the substrate support 110 may not be affected by a coating on the back surface 110A of the substrate support 110 or on the inner surface 114A of the lower window 114 as the coating can be reduced or eliminated using the coating removal process described above.

A temperature control process can be performed to adjust the temperature at the inner surface of the purge volume 132 (e.g., the lower window 114), based on the temperature measured with respect to the inner surface of the purge volume 132 (e.g., the lower window 114) on the opposite side of the substrate support 110 from the substrate W disposed thereon, by adjusting power provided to the upper heat sources 116 and lower heat sources 118. Various gas flow rates may also be adjusted to control the temperature at the lower window 114.

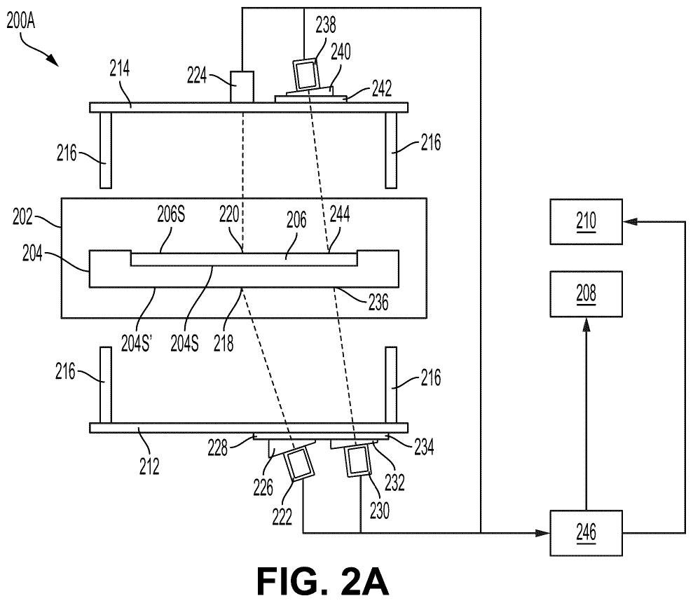

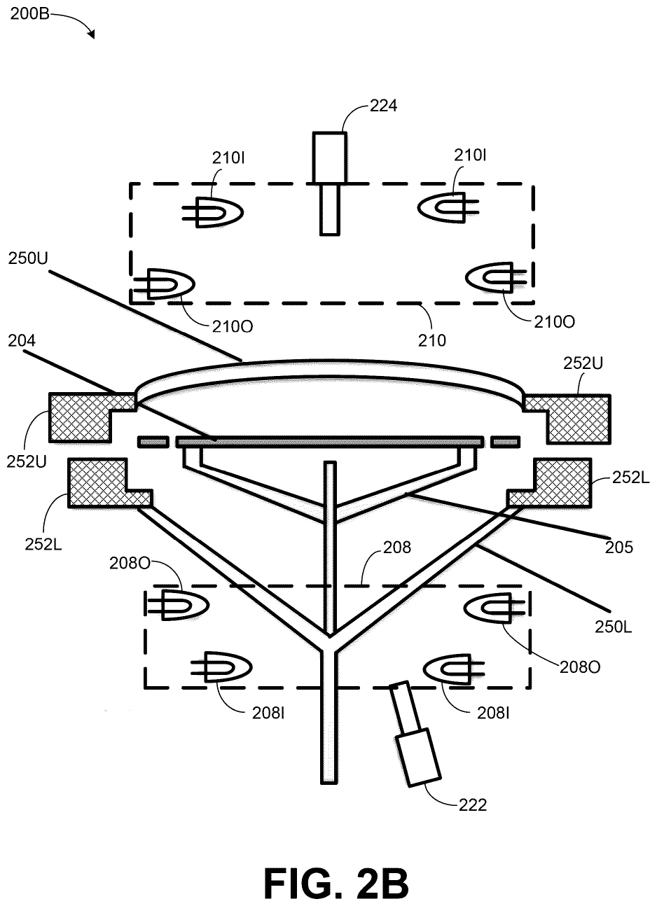

FIG. 2A is a schematic cross-sectional view of a system 200A that can implement thermal radiation profile control for epitaxial layer-to-layer uniformity, according to some embodiments. As shown in FIG. 2A, the system 200A can include a processing chamber 202 configured to perform a deposition process (e.g., an epitaxial deposition process). For example, the processing chamber 202 can include a deposition reactor such as an epitaxial deposition reactor. In some embodiments, system 200A corresponds to system 100 of FIG. 1.

A substrate support apparatus 204 that supports a substrate 206 on a top surface 204S of the substrate support apparatus 204 can be located within the deposition chamber 202. In some embodiments, the substrate support apparatus 204 is a disc shape having a diameter that ranges from about 280 millimeters (mm) to about 380 mm and the substrate 206 is, for example, a 300 mm wafer.

A set of bottom heat sources 208 can heat a bottom surface 204S′ of the substrate support apparatus 204 opposite the top surface 204S. The set of bottom heat sources 208 can have an inner zone and an outer zone (not shown). The inner zone and the outer zone of the set of bottom heat sources 208 can be independently controlled to heat an inner portion and an outer portion of the substrate support apparatus 204, respectively. Examples of heat sources that can be included in the set of bottom heat sources 208 include heating lamps, resistive heaters, LEDs, lasers, etc.

A set of top heat sources 210 can be used to separately heat the substrate 206. Similar to the set of bottom heat sources 208, the set of top heat sources 210 can have an inner zone and an outer zone (not shown). The inner zone and the outer zone of the top lamp module can be independently controlled to heat an inner portion and an outer portion of the substrate 206, respectively. Examples of heat sources that can be included in the set of top heat sources 210 include heating lamps, resistive heaters, LEDs, lasers, etc.

The system 200A further includes a bottom mounting plate 212 below the deposition chamber 202 and a top mounting plate 214 above the deposition chamber 202. Reflectors 116 are positioned above the bottom mounting plate 212 and below the top mounting plate 214 to reflect thermal radiation originating from the set of bottom heat sources 208 and the set of top heat sources 210, respectively.

The system 200A can include multiple thermal radiation detectors (“detectors”). Examples of detectors include pyrometers, thermometers, etc. For example, the system 200A can include a bottom center detector 222 disposed on the bottom mounting plate 212 to measure a temperature at a center location 218 of the bottom surface 204S′ of the substrate support apparatus 204, and a top center detector 224 disposed on the top mounting plate 214 to measure the temperature at a center location 220 of a top surface 206S of the substrate 206. In some embodiments, the bottom center detector 222 is mounted on an angle block 226 disposed on a mounting block 228 on the bottom mounting plate 212. A specific location of the bottom surface 204S′ of the substrate support apparatus 204 that the bottom center detector 222 measures can be determined by a viewing angle of the angle block 226 with respect to the bottom mounting plate 212 and a position of the mounting block 228 on the bottom mounting plate 212. In some embodiments, the angle block 226 and the mounting block 228 are adjusted such that the bottom center detector 222 measures the temperature at the center location 218. In some embodiments, the top center detector 224 is positioned directly above the center location 220 such that the top center detector 224 measures the temperature at the center location 220.

For measuring and monitoring the thermal radiation profiles of the substrate support apparatus 204 and the substrate 206, the system 200A can further include outer detectors to measure temperatures at outer locations of the bottom surface 204S′ of the substrate support apparatus 204 and the substrate 206. For example, the system 200A can include a bottom outer detector 230 mounted on an angle block 232 disposed on a mounting block 234 on the bottom mounting plate 212 to measure temperature at an outer location of the bottom surface 204S′ of the substrate support apparatus 204 that is spaced from the center location of the bottom surface 204S′ of the substrate support apparatus 204. An angle of the angle block 232 and a position of the mounting block 234 are adjusted such that the bottom outer detector 230 measures the temperature at the outer location 236 of the bottom surface 204S′ of the substrate support apparatus 204. The system 200A can further include a top outer detector 238 mounted on an angle block 240 disposed on a mounting block 242 on the top mounting plate 214 to measure temperature at an outer location 244 of the top surface 206S of the substrate 206 that is spaced from the center location 220. An angle of the angle block 240 and a position of the mounting block 242 can be adjusted such that the top outer detector 238 measures the temperature at the outer location 244 of the substrate 206. In some embodiments, the mounting block 242 is spaced from the top center detector 224 by a distance that ranges from about 180 mm to about 250 mm. In some embodiments, the angle of the angle block 240 ranges from about 90° to about 110° (e.g., about 100°) such that the top outer detector 238 measures thermal radiation at the outer location 244 spaced from the center location 220 by a distance that ranges from about 100 mm to about 150 mm.

Although FIG. 2A illustrates a single top outer detector 238, in some embodiments, multiple outer detectors 238 can be used to simultaneously measure temperatures at multiple locations of the top surface 206S of the substrate 206. With the top center detector 224 and the at least one top outer detector 238, thermal radiation profiles of the substrate 206 (e.g., a thermal radiation profile drift between a center of the substrate 206 and an outer of the substrate 206) can be measured.

Similarly, although FIG. 2A only illustrates one bottom outer detector 230, in some embodiments, multiple bottom outer detectors 230 can be used to simultaneously measure temperatures at multiple locations of the bottom surface 204S′ of the substrate support apparatus 204. With the bottom center detector 222 and the at least one bottom outer detector 230, thermal radiation profiles of the substrate support apparatus 204 (e.g., a thermal radiation profile drift between a center region of the substrate support apparatus 204 and an outer region of the substrate support apparatus 204) can be measured and controlled.

The bottom center detector 222 and the at least one bottom outer detector 230 can collectively form a set of bottom detectors. The top center detector 224 and the at least one top outer detector 238 can collectively form a set of top detectors.

The system 200A can further include at least one system controller 246. In some embodiments, the at least one controller 246 corresponds to the at least one system controller 166 of FIG. 1. The at least one system controller 246 can include a central processing unit (CPU), memory, support circuits (or I/O), and a user interface, such as graphics processing unit (GPU). The CPU may be one of any form of computer processors that are used in industrial settings for controlling various processes and hardware (e.g., pattern generators, motors, and other hardware) and monitor the processes (e.g., processing time and substrate position or location). The memory is connected to the CPU, and may be one or more of a readily available memory, such as random access memory (RAM), read only memory (ROM), floppy disk, hard disk, or any other form of digital storage, local or remote. Software instructions, algorithms and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the at least one system controller 246 determines which tasks are performable on the set of bottom heat sources 208 and/or the set of top heat sources 210. The program readable by the at least one system controller 246 may include a code to output feedback signal to the set of bottom heat sources 208 based on input data from the set of bottom detector, and code to output feedback signal to the set of top heat sources 210 based at least in part on an output of the at least system controller 246 with respect to the set of bottom heat sources 208.

The at least one system controller 246 can control the thermal radiation profile (e.g., temperature profile) of the substrate support apparatus 204. For example, to control the thermal radiation profile of the substrate support apparatus 204, the at least one system controller 246 can receive a bottom center thermal radiation measurement made by the bottom center detector 222 at the center location 218 (T_{BC}), and a bottom outer thermal radiation measurement made by the bottom outer detector 230 at the outer location 236 (T_{BS}). The at least one system controller 246 can determine whether the thermal radiation measurements satisfy a threshold condition. For example, the set of inputs can further include a predefined thermal radiation condition. In some embodiments, the predefined thermal radiation condition is user-defined. For example, the predefined thermal radiation condition can be experimentally determined by a user. The at least one system controller 246 can determine whether the bottom thermal radiation measurements satisfy the threshold condition by analyzing the thermal radiation measurements based on the predefined thermal radiation condition. In some embodiments, the predefined thermal radiation condition is based on a predefined thermal radiation (e.g., temperature) difference between the bottom center thermal radiation measurement and the at least one bottom outer thermal radiation measurement. For example, the predefined thermal radiation condition can be a single difference value or a range of difference values that correspond to a satisfactory thermal radiation profile across the substrate support apparatus 204. In these embodiments, the at least one system controller 246 can determine a measured thermal radiation (e.g., temperature) difference between T_{BC} and T_{BS} (T_{BC}−T_{BS}), and then compare T_{BC}−T_{BS} to the predefined thermal radiation difference to determine whether T_{BC}−T_{BS} satisfies the predefined thermal radiation difference (e.g., is approximately equal to a predefined thermal radiation difference value or is within a predefined range of thermal radiation difference values).

In some embodiments, the threshold condition (e.g., the predefined thermal radiation condition) is a static threshold condition. More specifically, the threshold condition can remain the same throughout all steps of the epitaxial deposition process. The static threshold condition can be user-defined.

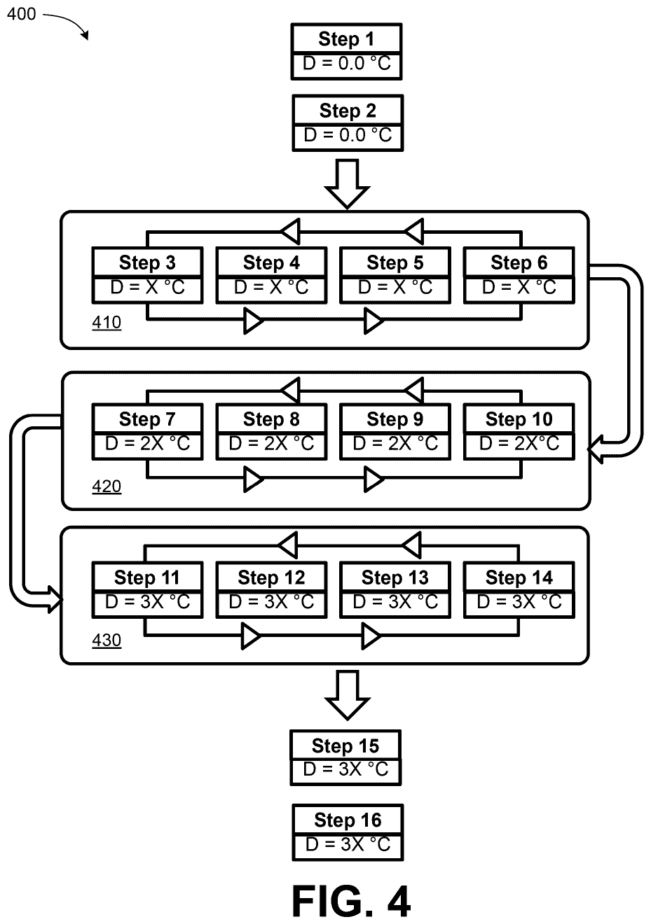

In some embodiments, the threshold condition is a variable threshold condition that varies throughout the epitaxial deposition process. Illustratively, if the threshold condition is a predefined thermal radiation difference, then the predefined thermal radiation difference can be increased (e.g., by a fixed rate) throughout the epitaxial deposition process. In some embodiments, the threshold condition varies based on a block of steps (“block”) of the epitaxial deposition process. A block of an epitaxial deposition process includes multiple steps that form a repeatable loop. Illustratively, if the threshold condition is a predefined thermal radiation difference, then the predefined thermal radiation difference can be increased for a current block after the completion of a previous block. For example, the predefined thermal radiation difference can be increased by a fixed amount. In some embodiments, each block is assigned a respective predefined thermal radiation difference as a threshold condition. Each predefined thermal radiation difference can be user-defined. For example, at least one offset data structure (e.g., table) that defines the respective predefined thermal radiation difference for each block can be stored by a user, and the at least one system controller 246 can use the at least one offset data structure to determine the predefined thermal radiation difference for each block throughout the epitaxial deposition process. An illustrative example of these embodiments will be described below with reference to FIG. 4.

If the at least one system controller 246 determines that the bottom thermal radiation measurements do not satisfy the threshold condition (e.g., the measured thermal radiation difference does not satisfy the predefined thermal radiation difference), then the at least one system controller 246 can take corrective action by modifying operation of the set of bottom heat sources 208. More specifically, the at least one system controller 246 can cause a modification of the power generated, or output, by the set of bottom heat sources 208 in order for the bottom thermal radiation measurements to satisfy the threshold condition (e.g., the measured thermal radiation difference satisfies the predefined thermal radiation difference).

In some embodiments, the set of bottom heat sources 208 includes a bottom inner zone of heat sources used to heat the bottom center region of the substrate support apparatus, and a bottom outer zone of heat sources used to heat a bottom outer region of the substrate support apparatus. An example of a bottom inner zone of heat sources and a bottom outer zone of heat sources will be described in further detail below with reference to FIG. 2B.

In some embodiments, the power generated by the bottom inner zone and the power generated by the bottom outer zone are dependently controlled (e.g., dependently controlled zones). For example, the set of bottom heat sources 208 can be allocated a power budget, and the bottom inner zone and the bottom outer zone can be allocated respective amounts of power from the power budget. More specifically, the bottom inner zone can be allocated a first amount of power (e.g., percentage) of the power budget and the bottom outer zone can be allocated a second amount of power (e.g., percentage) of the power budget, where the sum of the first amount of power and the second amount of power is approximately equal to the power budget (e.g., the percentages of the power budget add up to 100%). Thus, any increase or decrease to the first amount of power can result in a corresponding decrease or increase, respectively, to the second amount of power in accordance with the power budget (and vice versa). Accordingly, in these embodiments, the at least one system controller 246 can take corrective action by adjusting (e.g., increasing or decreasing) the first amount of power allocated to the bottom inner zone by a given magnitude and adjusting (e.g., decreasing or increasing) the second amount of power allocated to the bottom outer zone by the given magnitude in a manner determined to cause the bottom thermal radiation measurements to satisfy the threshold condition while maintaining the power budget.

In some embodiments, the power generated by the bottom inner zone and the power generated by the at least one bottom outer zone are independently controlled (e.g., independently controlled zones). For example, the power generated by the bottom inner zone can be adjusted by any amount without regard to the amount of power generated by the at least one bottom outer zone, and vice versa.

As an illustrative example, a predefined thermal radiation difference between a bottom center thermal radiation measurement and a bottom outer thermal radiation measurement for an epitaxial deposition process can be set for X ° C. (e.g., based on experimentation). Since the predefined thermal radiation difference is being defined based on a difference between the bottom center thermal radiation measurement and the bottom outer thermal radiation measurement (without loss of generality), then a positive value of X means that the threshold condition is satisfied if the bottom center thermal radiation measurement is greater than the bottom outer thermal radiation measurement by about X ° C., and a negative value of X means that the threshold condition is satisfies if the bottom center thermal radiation measurement is less than the bottom outer thermal radiation measurement by about X ° C. During the epitaxial deposition process, the at least one system controller 246 can determine that the measured thermal radiation difference between the bottom center thermal radiation measurement and the at least one bottom outer thermal radiation measurement is less than X ° C. (e.g., the bottom center location is emitting less thermal radiation than it should relative to the bottom outer location). In order to correct this, the at least one system controller 246 can cause an increase in the amount of power generated by the bottom inner zone and/or a decrease in the amount of power generated by the bottom outer zone of to cause the measured thermal radiation difference to be approximately equal to about X ° C. For example, the at least one system controller 246 can cause an increase in the amount of power generated by the bottom inner zone, and a corresponding decrease in the amount of power generated by the bottom outer zone. Similarly, if the measured thermal radiation difference is greater than X ° C., then the at least one system controller 246 can cause an increase in the amount of power generated by the bottom outer zone and/or a decrease in the amount of power generated by the bottom inner zone to cause the measured thermal radiation difference to be approximately equal to about X ° C. The at least one system controller 246 can continue monitoring the measured thermal radiation difference and make similar adjustments to the operation of the set of bottom heat sources 208 upon determining a deviation from the predefined thermal radiation difference.

Implementing thermal radiation profile control can further include controlling a thermal radiation profile (e.g., temperature profile) of the substrate 206 based on the thermal radiation profile control of the substrate support apparatus 204. More specifically, the at least one system controller 246 can control operation of the set of top heat sources 210 used to heat the substrate 206 (e.g., power generated by the set of top heat sources 210). In some embodiments, the at least one system controller 246 controls operation of the set of top heat sources 210 by adjusting the power generated by the set of top heat sources 210 by an amount proportional to the power generated by the set of bottom heat sources 208. More specifically, the power generated by the set of top heat sources 210 can be equal to the power generated by the set of bottom heater sources 208 multiplied by an adjustment factor.

In some embodiments, and similar to the set of bottom heat sources, the set of top heat sources 210 includes top inner zone of heat sources used to heat the top center region of the substrate 206, and a top outer zone of heat sources used to heat at least the top outer region of the substrate 206. In these embodiments, the at least one system controller 246 can proportionally adjust the power generated by the top inner zone and/or the power generated by the top outer zone. An example of a top inner zone of heat sources and a top outer zone of heat sources will be described in further detail below with reference to FIG. 2B.

In some embodiments, the power generated by the top inner zone and the power generated by the top outer zone are dependently controlled (e.g., similar to the set of bottom heat sources). In some embodiments, the power generated by the top inner zone and the power generated by the top outer zone are independently controlled.

In some embodiments, the adjustment factor is determined based on a ratio between a top heat source metric associated with the set of top heat sources 210, and a bottom heat source metric associated with the set of bottom heat sources 208. For example, a top heat source metric can be a number of top heat sources (e.g., of the top inner zone and/or the top outer zone), and a bottom heat source metric can be a number of bottom heat sources (e.g., of the bottom inner zone and/or the bottom outer zone). As another example, a top heat source metric can be a density of top heat sources (e.g., of the top inner zone and/or the top outer zone), and a bottom heat source metric can be a density of bottom heat sources (e.g., of the bottom inner zone and/or the bottom outer zone). As yet another example, a top heat source metric can be an amount of power generated by the set of top heat sources (e.g., by the top inner zone and/or the top outer zone), and a bottom heat source metric can be an amount of power generated by the set of bottom heat sources (e.g., by the bottom inner zone and/or the bottom outer zone). However, any suitable heat source metric can be used to determine the adjustment factor in accordance with embodiments described here. In some embodiments, the adjustment factor is determined based on an analysis of a relationship or correlation between thermal radiation measurements made by the set of bottom detectors and thermal radiation measurements made by the set of top detectors.

Accordingly, the at least one system controller 246 can use a closed-loop control scheme to automatically control operation of the set of bottom heat sources 208 (e.g., power generated by the set of bottom heat sources) based on a set of inputs, and use a dependent control scheme to automatically control operation of the set of top heat sources 210 (e.g., power generated by the set of top heat sources) based on the operation of the set of bottom heat sources 208.

It should be noted that embodiments described above are just some possible examples of thermal radiation profile control according to the present disclosure and do not limit the possible configurations, specifications, or the like of the thermal radiation profile and control. For example, embodiments described above can be applied not only to detect and control a thermal radiation profile drift on a single substrate during an epitaxy process but also to a thermal radiation profile drift between one substrate to another during multiple epitaxy processes. In this case, a baseline thermal radiation profile or an average thermal radiation profile of multiple thermal radiation profiles can be used as a reference to which the feedback control adjusts the thermal radiation profiles.

FIG. 2B is a schematic cross-sectional view of a system 200B that can implement thermal radiation profile control for epitaxial layer-to-layer uniformity, according to some embodiments. The system 200B can include the substrate support apparatus 204, the set of bottom detectors including the detector 222, the set of top detectors including the detector 224, the set of bottom heat sources 208, the set of top heat sources 210, as described above with reference to FIG. 2A.

As further shown in FIG. 2B, the system 200B can include a substrate support apparatus shaft and substrate lift 205, an upper dome 250U, a lower dome 250L, upper liners 252U and lower liners 252L. The set of bottom heat sources 208 can include a bottom inner zone having bottom inner zone heat sources 208I, and a bottom outer zone having bottom outer zone heat sources 208O. The set of top heat sources 210 can include a top inner zone having top inner zone heat sources 210I, and a top outer zone having top outer zone heat sources 210O. Accordingly, the heat sources can be divided into 4 total zones. In some embodiments, each of the zones is separately controlled by a respective power controller that has one analog input (voltage feedback) and two analog inputs (voltage and current feedbacks). In some embodiments, a power controller includes a silicon controlled rectifier (SCR).

Each of the zones can have any suitable number of heat sources in accordance with embodiments described herein. In some embodiments, the heat sources are heating lamps. In these embodiments, the bottom inner zone can include 12 lamps 208I, the bottom outer zone can include 32 lamps 208O, the top inner zone can include 20 lamps 210I, and the top outer zone can include 12 lamps 210O.

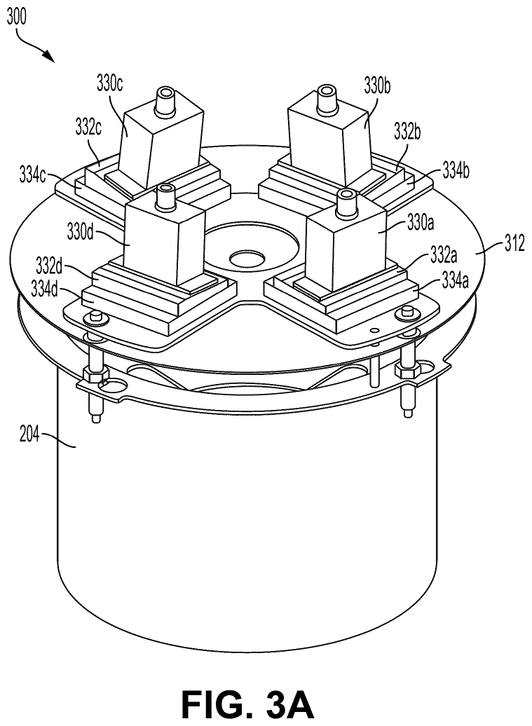

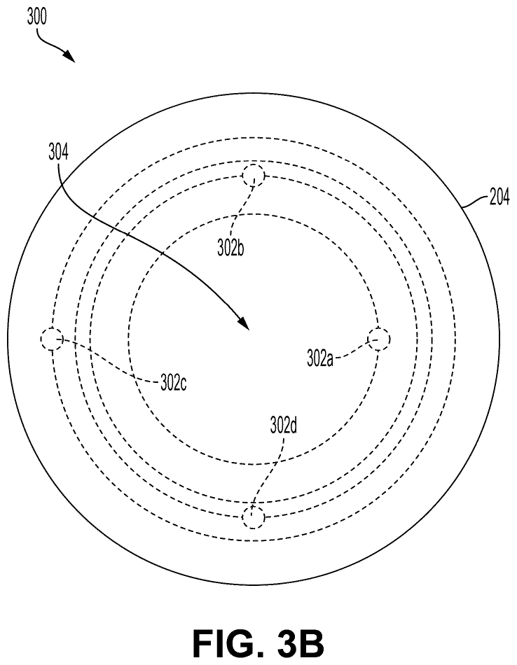

FIGS. 3A-3B are diagrams of an example system 300 including the substrate support apparatus 204 and a set of bottom detectors, according to some embodiments. In some embodiments, and as shown in FIG. 3A, the set of bottom detectors includes four bottom outer detectors 330a-d located on the bottom mounting plate 212. The bottom outer optical detectors 330a-d are respectively mounted on angle blocks 332a-d, which are respectively disposed on the mounting blocks 334a-d. The mounting blocks 334a-d are distributed around the bottom center detector 222 (not shown in FIG. 3A). In some embodiments, the mounting blocks 334a-d are spaced by a distance that ranges from about 50 mm to about 150 mm from a center of the bottom mounting plate 212. In some embodiment, the angles of the angle blocks 332a-d are set to 100°, 134°, 160°, and 140°. As shown in FIG. 3B, with this set of the angles, the bottom outer detectors 330a-d can measure temperatures at outer locations 302a-d of the bottom surface of the substrate support apparatus 204. In some embodiments, the outer locations 302a-d are spaced from a center location 304 of the bottom surface of the substrate support apparatus 204 by distances that range from about 100 to about 170 mm.

FIG. 4 is a diagram 400 illustrating an example method of implementing a variable threshold condition for thermal radiation profile control during a deposition process such as an epitaxial deposition process, according to some embodiments. In one example, an epitaxial deposition process (e.g., superlattice epitaxy) can includes multiple steps, and a portion of the steps can be divided into one or more blocks, where each block defines multiple steps that form a loop that can be executed one or more times. For example, as shown in FIG. 4, the deposition process in this illustrative example includes 16 steps, where step 3 through step 6 are included in a block 410 defining a first loop, step 7 through step 10 are included in a block 420 defining a second loop, and step 11 through step 14 are included in a block 430 defining a third loop.

The value “D” shown in FIG. 4 represents a predefined temperature difference between an inner bottom zone and an outer bottom zone. Initially, in this illustrative example, the predefined temperature difference is set to an initial temperature of 0.0° C. The predefined temperature difference can increase at a fixed or variable rate throughout the deposition process in an embodiment. In one example, the predefined temperature difference can increase by some fixed amount X during the next block in the deposition process.

For example, after step 2, the predefined temperature difference can increase from 0.0° C. to X ° C. to perform one or more iterations of the first loop defined by the block 410. The predefined temperature difference can stay at X ° C. through the duration of the one or more iterations of the first loop defined by the block 410. After the completion of the one or more iterations of the first loop defined by the block 410, the predefined temperature difference can increase from X ° C. to 2X ° C. to perform one or more iterations of the second loop defined by the block 420. The predefined temperature difference can stay at 2X ° C. through the duration of the one or more iterations of the second loop defined by the block 420. After the completion of the one or more iterations of the second loop defined by the block 420, the predefined temperature difference can increase from 2X ° C. to 3X ° C. to perform one or more iterations of the third loop defined by the block 430. The predefined temperature difference can stay at 3X ° C. through the duration of the one or more iterations of the third loop defined by the block 430. Since the block 430 is the final block, there are no additional changes to the predefined temperature difference. Thus, steps 15 and 16 are performed with the predefined temperature difference of 3X ° C.

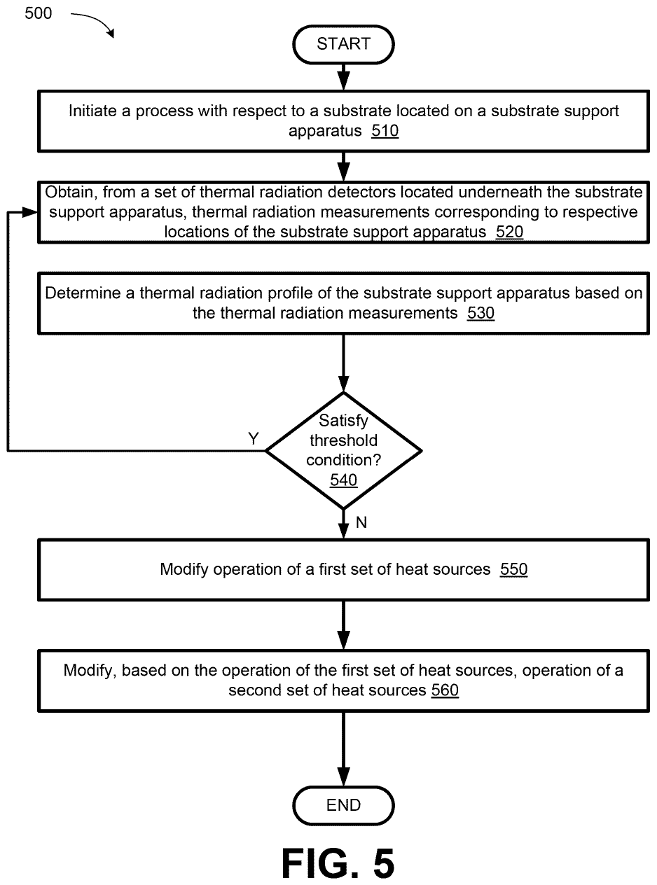

FIG. 5 is a flowchart of a method 500 for implementing thermal radiation profile control for epitaxial layer-to-layer uniformity, according to some embodiments. The method 500A is performed by a system that can include hardware (circuitry, dedicated logic, optical measuring tools as described herein, etc.), software (such as is run on a general purpose computer system or a dedicated machine), firmware, or some combination thereof. In some embodiments, the method 500 is performed by at least one system controller, such as the at least one controller 166 of FIG. 1 and/or the at least one system controller 246 of FIG. 2. In other or similar implementations, one or more operations of the method 500 can be performed by one or more other machines not depicted in the figures.

At operation 510, processing logic initiates a process with respect to a substrate located on a substrate support apparatus. In some embodiments, the process is a deposition process. For example, the deposition process can be an epitaxial deposition process (e.g., superlattice epitaxy).

At operation 520, processing logic obtains, from a set of thermal radiation detectors located underneath the substrate support apparatus, thermal radiation measurements corresponding to respective locations of the substrate support apparatus. For example, the thermal radiation thermal radiation measurements can include a bottom center measurement corresponding to a bottom center location of the substrate support apparatus, and a bottom outer measurement corresponding to a bottom outer location of the substrate support apparatus. In some embodiments, each thermal radiation measurement is a respective temperature measurement at the respective location. For example, the bottom center measurement can be a temperature measurement at the bottom center location of the substrate support apparatus, and the bottom outer measurement can be a temperature measurement at the bottom outer location of the substrate support apparatus.

At operation 530, processing logic determines, based on the thermal radiation measurements, a thermal radiation profile of the substrate support apparatus. In some embodiments, the thermal radiation profile is defined by a measured thermal radiation difference between the bottom center measurement and the bottom outer measurement. For example, the measured thermal radiation difference can be a measured temperature difference between the temperature measurement at the bottom center location of the substrate support apparatus and the temperature measurement at the bottom outer location of the substrate support apparatus.

At operation 540, processing logic determines whether the thermal radiation profile of the substrate support apparatus satisfies a threshold condition. In some embodiments, the threshold condition is a predefined thermal radiation condition. For example, the predefined thermal radiation condition can be a predefined temperature condition. In some embodiments, the predefined thermal radiation condition is user-defined. For example, the predefined thermal radiation condition can be experimentally determined by a user.

In some embodiments, the predefined thermal radiation condition is based on a predefined thermal radiation (e.g., temperature) difference between the bottom center thermal radiation measurement and the bottom outer thermal radiation measurement. For example, the predefined thermal radiation condition can be a single difference value or a range of difference values that correspond to a satisfactory thermal radiation profile across the substrate support apparatus. In these embodiments, determining whether the thermal radiation profile of the substrate support apparatus satisfies the threshold condition can include determining whether the measured thermal radiation difference satisfies the predefined thermal radiation difference (e.g., is approximately equal to a predefined thermal radiation difference value or is within a predefined range of thermal radiation difference values).

In some embodiments, the threshold condition (e.g., the predefined thermal radiation condition) is a static threshold condition. More specifically, the threshold condition can remain the same throughout all steps of the epitaxial deposition process. The static threshold condition can be user-defined.

In some embodiments, the threshold condition is a variable threshold condition that varies throughout the epitaxial deposition process. Illustratively, if the threshold condition is a predefined thermal radiation difference, then the predefined thermal radiation difference can be increased (e.g., by a fixed rate) throughout the epitaxial deposition process. In some embodiments, the threshold condition varies based on a block of steps (“block”) of the epitaxial deposition process. A block of an epitaxial deposition process includes multiple steps that form a repeatable loop. Illustratively, if the threshold condition is a predefined thermal radiation difference, then the predefined thermal radiation difference can be increased for a current block after the completion of a previous block. For example, the predefined thermal radiation difference can be increased by a fixed amount. In some embodiments, each block is assigned a respective predefined thermal radiation difference as a threshold condition. Each predefined thermal radiation difference can be user-defined. For example, at least one offset data structure (e.g., table) that defines the respective predefined thermal radiation difference for each block can be stored by a user, and the at least one system controller can use the at least one offset data structure to determine the predefined thermal radiation difference for each block throughout the epitaxial deposition process.

If not, the process can revert back to operation 520 to continue obtaining thermal radiation measurements during the epitaxial deposition process. Otherwise, at operation 550, processing logic modifies operation of a first set of heat sources. The first set of heat sources can be located underneath the substrate support apparatus (e.g., a set of bottom heat sources). More specifically, modifying operation of the first set of heat sources can include causing a modification of the power generated, or output, by the first set of heat sources in order for thermal radiation profile to satisfy the threshold condition (e.g., the measured thermal radiation difference satisfies the predefined thermal radiation difference).

In some embodiments, the first set of heat sources includes an inner zone of heat sources used to heat the bottom center region of the substrate support apparatus, and an outer zone of heat sources used to heat a bottom outer region of the substrate support apparatus. In some embodiments, the power generated by the inner zone of the first set of heat sources and the power generated by the outer zone of the first set of heat sources are dependently controlled (e.g., dependently controlled zones). For example, the first set of heat sources can be allocated a power budget, and the inner zone of the first set of heat sources and the outer zone of the first set of heat sources can be allocated respective amounts of power from the power budget. More specifically, the inner zone of the first set of heat sources can be allocated a first amount of power (e.g., percentage) of the power budget and the outer zone of the first set of heat sources can be allocated a second amount of power (e.g., percentage) of the power budget, where the sum of the first amount of power and the second amount of power is equal to the power budget (e.g., the percentages of the power budget add up to 100%). Thus, any increase or decrease to the first amount of power can result in a corresponding decrease or increase, respectively, to the second amount of power in accordance with the power budget (and vice versa). Accordingly, in these embodiments, modifying operation of the first set of heat sources can include adjusting (e.g., increasing or decreasing) the first amount of power allocated to the inner zone of the first set of heat sources by a given magnitude and adjusting (e.g., decreasing or increasing) the second amount of power allocated to the outer zone of the first set of heat sources by the given magnitude in a manner determined to cause the bottom thermal radiation measurements to satisfy the threshold condition while maintaining the power budget. In some embodiments, the power generated by the bottom inner zone and the power generated by the at least one bottom outer zone are independently controlled (e.g., independently controlled zones). For example, the power generated by the bottom inner zone can be adjusted by any amount without regard to the amount of power generated by the at least one bottom outer zone, and vice versa.

At operation 560, processing logic modifies operation of a second set of heat sources based on the operation of the first set of heat sources. The second set of heat sources can be located above the substrate support apparatus (e.g., a set of top heat sources) used to heat the substrate. In some embodiments, the at least one system controller modifies operation of the second set of heat sources by adjusting the power generated by the second set of heat sources by an amount proportional to the power generated by the first set of heat sources. More specifically, the power generated by the second set of heat sources can be equal to the power generated by the first set of heat sources multiplied by an adjustment factor. In some embodiments, and similar to the first set of heat sources, the second set of heat sources includes inner zone of heat sources used to heat the top center region of the substrate, and an outer zone of heat sources used to heat at least the top outer region of the substrate. In these embodiments, the power generated by the inner zone of the second set of heat sources and/or the power generated by the outer zone of the second set of heat sources can be proportionally adjusted.

In some embodiments, the power generated by the inner zone of the second set of heat sources and the power generated by the outer zone of the second set of heat sources are dependently controlled (e.g., similar to the set of bottom heat sources). In some embodiments, the power generated by the inner zone of the second set of heat sources and the power generated by the outer zone of the second set of heat sources are independently controlled.

In some embodiments, the adjustment factor is determined based on a ratio between a second heat source metric associated with the second set of heat sources, and a first heat source metric associated with the first set of heat sources. For example, a second heat source metric can be a number of heat sources of the second set of heat sources (e.g., of the inner zone and/or the outer zone), and a first heat source metric can be a number of heat sources of the first set of heat sources (e.g., of the inner zone and/or the outer zone). As another example, a second heat source metric can be a density of heat sources of the second set of heat sources (e.g., of the inner zone and/or the outer zone), and a first heat source metric can be a density of heat sources of the first set of heat sources (e.g., of the inner zone and/or the outer zone). As yet another example, a second heat source metric can be an amount of power generated by the second set of heat sources (e.g., by the inner zone and/or the outer zone), and a first heat source metric can be an amount of power generated by the first set of heat sources (e.g., by the inner zone and/or the outer zone). However, any suitable heat source metric can be used to determine the adjustment factor in accordance with embodiments described here. In some embodiments, the adjustment factor is determined based on an analysis of a relationship or correlation between thermal radiation measurements made by the set of thermal radiation detectors located underneath the substrate support apparatus, and the thermal radiation measurements made by the set of thermal radiation detectors located above the substrate support apparatus.

Accordingly, the at least one system controller can use a closed-loop control scheme to automatically control operation of the first set of heat sources (e.g., power generated by the first set of heat sources) based on a set of inputs, and use a dependent control scheme to automatically control operation of the second set of heat sources (e.g., power generated by the second set of heat sources) based on the operation of the first set of heat sources. Further details regarding operations 510-560 are described above with reference to FIGS. 1-4.

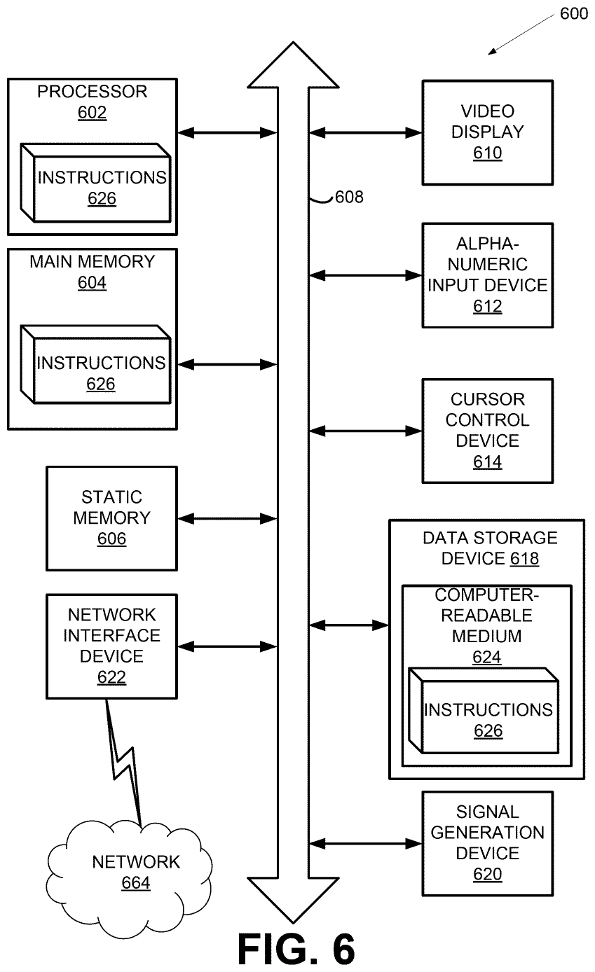

FIG. 6 depicts a diagrammatic representation of a machine in the example form of a computing device 600 within which a set of instructions, for causing the machine to perform any one or more of the methodologies discussed herein, can be executed. In alternative embodiments, the machine can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 600 can correspond to the controller 160 of FIG. 1 and/or the bow monitoring system 460 of FIG. 4.

The example computing device 600 includes a processing device 602, a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 818), which communicate with each other via a bus 608.

Processing device 602 can represent one or more general-purpose processors such as a microprocessor, central processing unit, or the like. More particularly, the processing device 602 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. Processing device 602 can also be or include a system on a chip (SoC), programmable logic controller (PLC), or other type of processing device. Processing device 602 is configured to execute the processing logic for performing operations discussed herein.

The computing device 600 can further include a network interface device 622 for communicating with a network 664. The computing device 600 also can include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 620 (e.g., a speaker).

The data storage device 618 can include a machine-readable storage medium (or more specifically a non-transitory computer-readable storage medium) 624 on which is stored one or more sets of instructions 626 embodying any one or more of the methodologies or functions described herein. A non-transitory storage medium refers to a storage medium other than a carrier wave. The instructions 626 can also reside, completely or at least partially, within the main memory 804 and/or within the processing device 602 during execution thereof by the computer device 600, the main memory 604 and the processing device 602 also constituting computer-readable storage media.

While the computer-readable storage medium 624 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a memory; and
at least one processing device, operatively coupled with the memory, to:
initiate a process with respect to a substrate located on a substrate support apparatus;
obtain, from a set of thermal radiation detectors located underneath the substrate support apparatus, a plurality of thermal radiation measurements, each thermal radiation measurement of the plurality of thermal radiation measurements corresponding to a respective location of the substrate support apparatus;
determine a thermal radiation profile of the substrate support apparatus based on the plurality of thermal radiation measurements;
determine whether the thermal radiation profile of the substrate support apparatus satisfies a threshold condition;
in response to determining that the thermal radiation profile of the substrate support apparatus does not satisfy the threshold condition, modify operation of a first set of heat sources to adjust the thermal radiation profile of the substrate support apparatus; and
modify, based at least in part on the operation of the first set of heat sources, operation of a second set of heat sources to adjust a thermal radiation profile of the substrate.

2. The system of claim 1, wherein the process is an epitaxial deposition process.

3. The system of claim 2, wherein the epitaxial deposition process is superlattice epitaxy.

4. The system of claim 1, wherein:
the thermal radiation profile of the substrate support apparatus is associated with a measured thermal radiation difference between a first measurement corresponding to a center location of the substrate support apparatus and a second measurement corresponding to an outer location of the substrate support apparatus; and
to determine whether the thermal radiation profile of the substrate support apparatus satisfies the threshold condition, the at least one processing device is to determine whether the measured thermal radiation difference satisfies a thermal radiation difference criterion.

5. The system of claim 1, wherein, to modify the operation of the first set of heat sources, the at least one processing device is to adjust at least one of: a first amount of power generated by an inner zone of the first set of heat sources, or a second amount of power generated by an outer zone of the first set of heat sources.

6. The system of claim 1, wherein, to modify the operation of the second set of heat sources, the at least one processing device is to modify an amount of power generated by the second set of heat sources in proportion to an amount of power generated by the first set of heat sources based on an adjustment factor, and wherein the adjustment factor is determined based on a first heat source metric associated with the first set of heat sources and a second heat source metric associated with the second set of heat sources.

7. The system of claim 1, wherein the threshold condition is a variable threshold condition that changes based on a block corresponding to a loop of steps of the process.

8. A method comprising:
initiating, by at least one processing device, a process with respect to a substrate located on a substrate support apparatus;
obtaining, by the at least one processing device from a set of thermal radiation detectors located underneath the substrate support apparatus, a plurality of thermal radiation measurements, each thermal radiation measurement of the plurality of thermal radiation measurements corresponding to a respective location of the substrate support apparatus;
determining, by the at least one processing device, a thermal radiation profile of the substrate support apparatus based on the plurality of thermal radiation measurements;
determining, by the at least one processing device, whether the thermal radiation profile of the substrate support apparatus satisfies a threshold condition;
in response to determining that the thermal radiation profile of the substrate support apparatus does not satisfy the threshold condition, modifying, by the at least one processing device, operation of a first set of heat sources to adjust the thermal radiation profile of the substrate support apparatus; and
modifying, by the at least one processing device based at least in part on the operation of the first set of heat sources, operation of a second set of heat sources to adjust a thermal radiation profile of the substrate.

9. The method of claim 8, wherein the process is an epitaxial deposition process.

10. The method of claim 9, wherein the epitaxial deposition process is superlattice epitaxy.

11. The method of claim 8, wherein:
the thermal radiation profile of the substrate support apparatus is associated with a measured thermal radiation difference between a first measurement corresponding to a center location of the substrate support apparatus and a second measurement corresponding to an outer location of the substrate support apparatus; and
determining whether the thermal radiation profile of the substrate support apparatus satisfies the threshold condition comprises determining whether the measured thermal radiation difference satisfies a thermal radiation difference criterion.

12. The method of claim 8, wherein modifying the operation of the first set of heat sources comprises adjusting at least one of: a first amount of power generated by an inner zone of the first set of heat sources, or a second amount of power generated by an outer zone of the first set of heat sources.

13. The method of claim 8, wherein modifying the operation of the second set of heat sources comprises modifying an amount of power generated by the second set of heat sources in proportion to an amount of power generated by the first set of heat sources based on an adjustment factor, and wherein the adjustment factor is determined based on a first heat source metric associated with the first set of heat sources and a second heat source metric associated with the second set of heat sources.

14. The method of claim 8, wherein the threshold condition is a variable threshold condition that changes based on a block corresponding to a loop of steps of the process.

15. A system comprising:
a processing chamber comprising a substrate support apparatus;
a first set of thermal radiation detectors located below the substrate support apparatus;
a second set of thermal radiation detectors located above the substrate support apparatus;
a first set of heat sources configured to heat the substrate support apparatus;
a second set of heat sources configured to heat a substrate located on the substrate support apparatus; and
at least one system controller configured to:
initiate a process with respect to the substrate;
obtain, from the first set of thermal radiation detectors, a plurality of thermal radiation measurements, each thermal radiation measurement of the plurality of thermal radiation measurements corresponding to a respective location of the substrate support apparatus;
determine a thermal radiation profile of the substrate support apparatus based on the plurality of thermal radiation measurements;
determine whether the thermal radiation profile of the substrate support apparatus satisfies a threshold condition;
in response to determining that the thermal radiation profile of the substrate support apparatus does not satisfy the threshold condition, modify operation of the first set of heat sources to adjust the thermal radiation profile of the substrate support apparatus; and
modify, based at least in part on the operation of the first set of heat sources, operation of the second set of heat sources to adjust a thermal radiation profile of the substrate.

16. The system of claim 15, wherein the process is an epitaxial deposition process.

17. The system of claim 15, wherein:
the set of thermal radiation detectors comprises a center detector and an outer detector;
the thermal radiation profile of the substrate support apparatus is associated with a measured thermal radiation difference between a first measurement corresponding to a center location of the substrate support apparatus measured by the center detector, and a second measurement corresponding to an outer location of the substrate support apparatus measured by the outer detector; and
to determine whether the thermal radiation profile of the substrate support apparatus satisfies a threshold condition, the at least one processing device is to determine whether the measured thermal radiation difference satisfies a thermal radiation difference criterion.

18. The system of claim 15, wherein, to modify the operation of the first set of heat sources, the at least one processing device is to adjust at least one of: a first amount of power generated by an inner zone of the first set of heat sources, or a second amount of power generated by an outer zone of the first set of heat sources.

19. The system of claim 15, wherein, to modify the operation of the second set of heat sources, the at least one processing device is to modify an amount of power generated by the second set of heat sources in proportion to an amount of power generated by the first set of heat sources based on an adjustment factor, and wherein the adjustment factor is determined based on a first heat source metric associated with the first set of heat sources and a second heat source metric associated with the second set of heat sources.

20. The system of claim 15, wherein the threshold condition is a variable threshold condition that changes based on a block corresponding to a loop of steps of the process.
